(19) United States
(12) Patent Application Publication
(10) Pub. No.: US 2025/0132155 A1
(43) Pub. Date: Apr. 24, 2025

(54) APPARATUS, SYSTEMS, AND METHODS OF USING ATOMIC HYDROGEN RADICALS WITH SELECTIVE EPITAXIAL DEPOSITION

(71) Applicant: Applied Materials, Inc., Santa Clara, CA (US)

(72) Inventors: Chen-Ying WU, Santa Clara, CA (US); Yi-Chiau HUANG, Fremont, CA (US); Zhiyuan YE, San Jose, CA (US); Schubert S. CHU, San Francisco, CA (US); Errol Antonio C. SANCHEZ, Tracy, CA (US); Brian Hayes BURROWS, San Jose, CA (US)

(21) Appl. No.: 18/983,235

(22) Filed: Dec. 16, 2024

Related U.S. Application Data
(63) Continuation of application No. 18/954,712, filed on Nov. 21, 2024.
Application No. 18/954,712 is a continuation of application No. 17/099,454, filed on Nov. 16, 2020.

(51) Int. Cl. H01L 21/02; C30B 25/08; C30B 25/18; C30B 29/06; C30B 33/02; C30B 33/12; C30B 35/00; H01L 21/3065; H01L 21/324

(52) U.S. Cl. CPC H01L 21/02636; C30B 25/08; C30B 25/18; C30B 33/02; C30B 33/12; C30B 35/00; H01L 21/02532; H01L 21/3065; H01L 21/324; C30B 29/06; Y10T 117/10

(57) ABSTRACT

Aspects of the present disclosure relate to apparatus, systems, and methods of using atomic hydrogen radicals with epitaxial deposition. In one aspect, nodular defects (e.g., nodules) are removed from epitaxial layers of substrate. In one implementation, a method of processing substrates includes selectively growing an epitaxial layer on one or more crystalline surfaces of a substrate. The epitaxial layer includes silicon. The method also includes etching the substrate to remove a plurality of nodules from one or more non-crystalline surfaces of the substrate. The etching includes exposing the substrate to atomic hydrogen radicals. The method also includes thermally annealing the epitaxial layer to an anneal temperature that is 600 degrees Celsius or higher.

### CROSS-REFERENCE TO RELATED APPLICATIONS

This application is a continuation of co-pending U.S. patent application Ser. No. 18/954,712, filed Nov. 21, 2024, which is a continuation of co-pending U.S. patent application Ser. No. 17/099,454, filed Nov. 16, 2020. Each of these applications are herein incorporated by reference.

### BACKGROUND

### Field

Aspects of the present disclosure relate to apparatus, systems, and methods of using atomic hydrogen radicals with epitaxial deposition. In one aspect, nodular defects (e.g., nodules) are removed following selective growth of epitaxial layers on a substrate.

### Description of the Related Art

Epitaxial deposition is a deposition process that may be used to grow layers on crystalline surfaces of substrates. However, in selective epitaxial growth of epitaxial layers, some residual or non-selective growth can occur in undesired locations, causing defects. Additionally, removing non-selective growth in undesired locations can damage epitaxial layers or otherwise interfere with the epitaxial layers.

Therefore, there is a need for improved methods, apparatus, and systems that remove residual or non-selective growth in undesired locations at a reduced or eliminated probability of damage to or interference with epitaxial layers.

### SUMMARY

Aspects of the present disclosure relate to apparatus, systems, and methods of using atomic hydrogen radicals with epitaxial deposition. In one aspect, following growth of epitaxial layers on a substrate, nodular defects (e.g., nodules) which are residual or non-selective growth on certain areas of the substrate are removed.

In one implementation, a method of processing substrates includes selectively growing an epitaxial layer on one or more crystalline surfaces of a substrate. The epitaxial layer includes silicon. The method also includes etching the substrate to remove a plurality of nodules from one or more non-crystalline surfaces of the substrate. The etching includes exposing the substrate to atomic hydrogen radicals. The method also includes thermally annealing the epitaxial layer to an anneal temperature that is 600 degrees Celsius or higher.

In one implementation, a system for processing substrates includes one or more processing chambers, and a controller. The controller includes instructions that, when executed, cause the one or more processing chambers to selectively grow an epitaxial layer on one or more crystalline surfaces of a substrate. The epitaxial layer includes silicon. The instructions, when executed, also cause the one or more processing chambers to etch the substrate to remove a plurality of nodules from one or more dielectric surfaces of the substrate. The etching includes exposing the substrate to atomic hydrogen radicals. The instructions, when executed, also cause the one or more processing chambers to thermally anneal the epitaxial layer to an anneal temperature that is 600 degrees Celsius or higher.

In one implementation, a system for processing substrates includes a processing chamber having an interior volume, a plasma source coupled to the processing chamber, and a controller. The controller includes instructions that, when executed, cause the processing chamber to selectively grow an epitaxial layer on one or more crystalline surfaces of a substrate. The epitaxial layer includes silicon. The instructions, when executed, also cause the processing chamber to etch the substrate to remove a plurality of nodules from one or more dielectric surfaces of the substrate. The etching includes generating atomic hydrogen radicals using the plasma source, and exposing the substrate to the atomic hydrogen radicals within the interior volume. The instructions, when executed, also cause the processing chamber to thermally anneal the epitaxial layer.

### BRIEF DESCRIPTION OF THE DRAWINGS

So that the manner in which the above-recited features of the disclosure can be understood in detail, a more particular description of the disclosure, briefly summarized above, may be had by reference to implementations, some of which are illustrated in the appended drawings. It is to be noted, however, that the appended drawings illustrate only common implementations of this disclosure and are therefore not to be considered limiting of its scope, for the disclosure may admit to other equally effective implementations.

FIG. 1 is a schematic view of a method of processing substrates, according to one implementation.

FIG. 2 is a schematic view of a system for processing substrates, according to one implementation.

FIG. 3 is a schematic cross-sectional view of a processing chamber, according to one implementation.

FIG. 4 is a schematic cross-sectional view of a processing chamber, according to one implementation.

FIG. 5 is a schematic cross-sectional view of a processing chamber, according to one implementation.

FIG. 6 is a schematic cross-sectional view of a processing chamber, according to one implementation.

To facilitate understanding, identical reference numerals have been used, where possible, to designate identical elements that are common to the figures. It is contemplated that elements disclosed in one implementation may be beneficially utilized on other implementations without specific recitation.

### DETAILED DESCRIPTION

Aspects of the present disclosure relate to apparatus, systems, and methods of using atomic hydrogen radicals with epitaxial deposition. In one aspect, nodular defects (e.g., nodules) are removed following selective growth of epitaxial layers on a substrate.

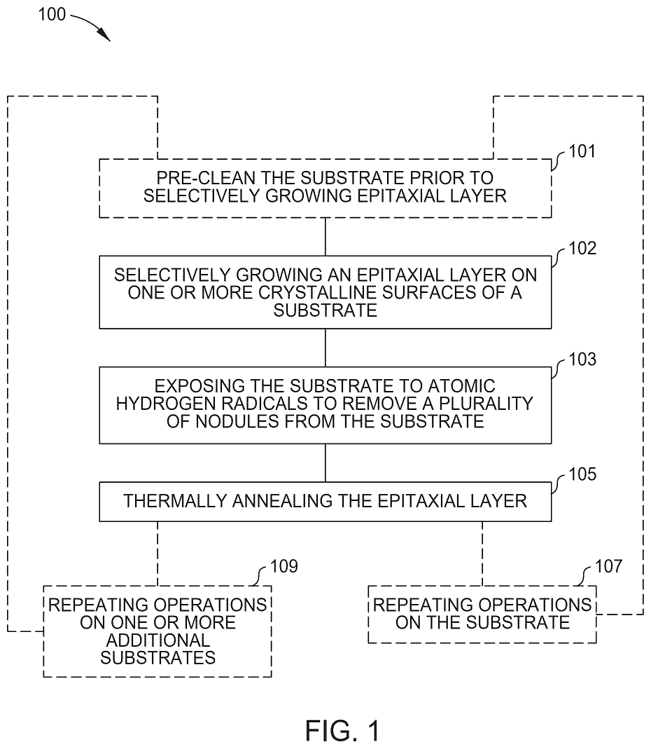

FIG. 1 is a schematic view of a method 100 of processing substrates, according to one implementation. Operation 101 of the method includes pre-cleaning the substrate prior to selectively growing an epitaxial layer on a substrate. The pre-cleaning removes one or more contaminants from one or more crystalline surfaces of the substrate. The contaminants include native oxide or other contaminants.

Operation 102 of the method 100 includes selectively growing an epitaxial layer on the one or more crystalline surfaces of the substrate. The epitaxial layer includes silicon, doped silicon, germanium, doped germanium, silicon germanium, doped silicon germanium, germanium tin, silicon germanium tin, gallium arsenide, indium arsenide, indium phosphide, gallium nitride, and/or aluminum gallium nitride. The one or more crystalline surfaces are exposed surfaces that at least partially define an epitaxial window. The substrate also includes one or more non-crystalline surfaces, such as one or more dielectric surfaces, that are outside of the epitaxial window. In one embodiment, which can be combined with other embodiments, the epitaxial layer is selectively grown at a growth temperature within a range of 200 degrees Celsius to 800 degrees Celsius.

The selectively growing the epitaxial layer includes exposing the substrate to one or more silicon-containing gases, one or more carrier gases such as H2, N2, Ar, and/or He, one or more germanium-containing gases, hydrogen chloride (HCl), chlorine gas (Cl2), and/or hydrogen bromide (HBr). The one or more silicon-containing gases include one or more silanes, such as silane (SiH4), disilane (Si₂H₆,), dichlorosilane (SiH₂Cl₂), hexachlorodisilane (Si₂Cl₆), dibromosilane (SiH₂Br₂), and/or higher order silane derivatives thereof. The one or more germanium-containing gases include one or more of germane (GeH₄), digermane (Ge₂H₆), germanium tetrachloride (GeCl₄), dichlorogermane (GeH₂Cl₂), and/or derivatives thereof. The selectively growing the epitaxial layer also includes exposing the substrate to one or more dopant gases. In one embodiment, which can be combined with other embodiments, the one or more dopant gases include one or more of diborane (B₂H₆), boron trichloride (BCl₃), phosphine, phosphorous trichloride (PCl₃), tertiarybutylphosphine (TBP), silylphosphines, arsine (AsH₃), tertiarybutylarsine (TBA), triethylantimony (TESb), tin chloride (SnCl₄), and trimethylgallium (TMGa).

During the selectively growing, nodular defects (e.g., nodules) can form on the one or more non-crystalline surfaces that are outside of the epitaxial window. Operation 103 includes etching the substrate to remove a plurality of nodules from the substrate. The etching includes exposing the substrate to atomic hydrogen radicals. In one embodiment, which can be combined with other embodiments, the substrate is exposed to the atomic hydrogen radicals at an etch temperature that is 600 degrees Celsius or less. The atomic hydrogen radicals include hydrogen atoms that include an unpaired valence electron. The atomic hydrogen radicals are a part of a hydrogen plasma to which the substrate is exposed. In one embodiment, which can be combined with other embodiments, both the one or more crystalline surfaces within the epitaxial window and the one or more non-crystalline surfaces outside of the epitaxial window are exposed to the atomic hydrogen radicals to remove the plurality of nodules from the non-crystalline surfaces. In one embodiment, which can be combined with other embodiments, the substrate is exposed to the atomic hydrogen radicals at an etch pressure within a range 5 mTorr to 500 mTorr, and a flow rate within a range of 100 standard cubic centimeters per minute (SCCM) to 300 SCCM. In one embodiment, which can be combined with other embodiments, the exposing the substrate to the atomic hydrogen radicals includes exposing one or more dielectric surfaces of the substrate to the atomic hydrogen radicals to remove the plurality of nodules from the one or more dielectric surfaces. In one embodiment, which can be combined with other embodiments, the atomic hydrogen radicals are generated by filtering (such as by using an ion filter) or otherwise removing ions from plasma species having hydrogen. In one embodiment, which can be combined with other embodiments, the atomic hydrogen radicals are generated in-situ in a process chamber. In one embodiment, which can be combined with other embodiments, the atomic hydrogen radicals are generated in a remote plasma source coupled to a process chamber.

Operation 105 includes thermally annealing the epitaxial layer that is formed at operation 102 to an anneal temperature. The anneal temperature is 600 degrees Celsius or higher. In one embodiment, which can be combined with other embodiments, the thermally annealing the epitaxial layer to the anneal temperature includes exposing the epitaxial layer to one or more of hydrogen (H2) and/or one or more inert gases while heating the epitaxial layer to the anneal temperature. The epitaxial layer is heated to the anneal temperature using one or more heat lamps and/or one or more resistive heaters. In one embodiment, which can be combined with other embodiments, the epitaxial layer is exposed to the one or more of hydrogen (H2) and/or the one or more inert gases at a flow rate that is within a range of 1.0 standard liters per minute (SLM) to 30.0 SLM during the thermal annealing. In one embodiment, which can be combined with other embodiments, the one or more inert gases include one or more of nitrogen (N₂), helium (He) and/or argon (Ar). In one embodiment, which can be combined with other embodiments, the thermal annealing of operation 105 is conducted at an anneal pressure that is within a range of 5 Torr to 300 Torr.

The thermal annealing facilitates removing hydrogen from the epitaxial layer (such as hydrogen that may have been implanted during the exposing operation) and facilitates device integration and performance for a device having the epitaxial layer. The thermal annealing also facilitates diffusion of atoms at the near surface region of the crystalline structures to facilitate smoothing out any atomic scale roughness caused by the etching.

In one embodiment, which can be combined with other embodiments, the method 100 includes operation 107. Operation 107 includes repeating operations 101, 102, 103, 105 one or more additional times on the same substrate. In one example, which can be combined with other examples, operations 101, 102, 103, and 105 are repeated two additional times on the substrate to form a second epitaxial layer and a third epitaxial layer on the substrate that are each etched and thermally annealed. The present disclosure contemplates that the repeating of operation 107 can omit one or more of the operations 101, 102, 103, and/or 105. In one example, which can be combined with other examples, operation 107 omits operation 101 and includes repeating operations 102, 103, and 105 on the same substrate. In such an example, the same substrate remains under vacuum as the method 100 moves from operation 102, to operation 103, to operation 105, and back to operation 102 pursuant to operation 107.

In one embodiment, which can be combined with other embodiments, the method 100 includes operation 109. Operation 109 includes repeating operations 101, 102, 103, 105 on one or more additional substrates. In one example, which can be combined with other examples, operations 101, 102, 103, and 105 are repeated on a second substrate and a third substrate to form one or more epitaxial layers on the second substrate and the third substrate that are each etched and thermally annealed.

In one embodiment, which can be combined with other embodiments the operations 101, 102, 103, 105, 107, and/or 109 are conducted in a single processing chamber. In one example, which can be combined with other examples, some but not all of the operations 101, 102, 103, 105, 107, and/or 109 are conducted in the single processing chamber.

In one embodiment, which can be combined with other embodiments, a non-transitory computer-readable medium includes instructions that, when executed, cause a system to conduct the operations 101, 102, 103, 105, 107, and/or 109 of the method. In one example, which can be combined with other examples, the non-transitory computer-readable medium includes a controller that includes the instructions.

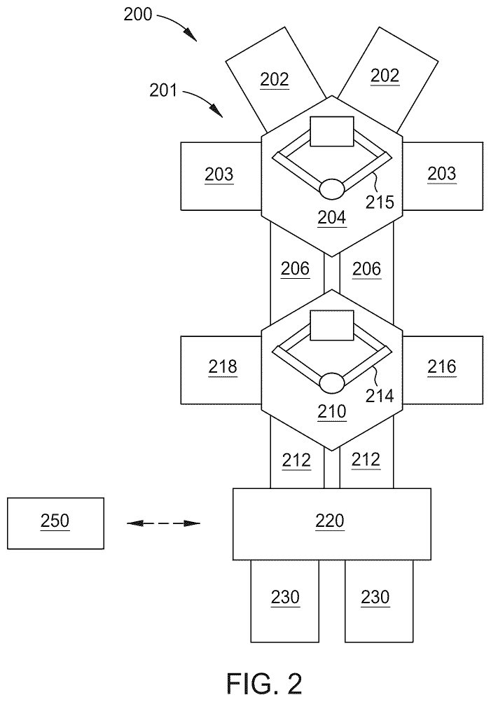

FIG. 2 is a schematic view of a system 200 for processing substrates, according to one implementation. The system 200 can be used to conduct the operations of the method 100 shown in FIG. 1. The system 200 includes a cluster tool 201. The cluster tool 201 of the system 200 includes one or more processing chambers 202, 203, 216, 218 (a plurality of processing chambers 202, 203, 216, 218 are shown) coupled to one or more transfer chambers 204 and 210.

A first transfer chamber 204 is coupled to one or more epitaxy chambers 202. The first transfer chamber 204 has a centrally disposed transfer robot 215 for transferring substrates between the epitaxy chambers 202, the etch chambers 203, and a plurality of pass-through stations 206. The first transfer chamber 204 is coupled via the pass-through stations 206 to a second transfer chamber 210, which is coupled to a cleaning chamber 216 for cleaning the substrates and to an anneal chamber 218. The second transfer chamber 210 has a centrally disposed transfer robot 214 for transferring substrates between a set of load lock chambers 212 and the cleaning chamber 216. A factory interface 220 is connected to the second transfer chamber 210 by the load lock chambers 212. The factory interface 220 is coupled to one or more pods 230 on the opposite side of the load lock chambers 212. The pods 230 typically are front opening unified pods (FOUP) that are accessible from the clean room in which the cluster tool 201 is disposed.

During operation, substrates are first transferred to the cleaning chamber 216 in which the substrates are pre-cleaned, as described for operation 101. The substrates are then transferred to one or more epitaxy chambers 202 to selectively grow an epitaxial layer on the substrates, as described for operation 102 of the method 100. The substrates are then transferred to one or more etch chambers 203, in which the substrates are exposed to atomic hydrogen radicals to etch the substrates and remove nodules from the substrates, as described for operation 103. The substrates are then transferred to the anneal chamber 218, in which the epitaxial layers formed on the substrates are annealed to an anneal temperature, as described for operation 105.

The first transfer chamber 204 and second transfer chamber 210 are held under vacuum during operations such that the transfer robots 214 and 215 transfers substrates under vacuum between all the processing chambers, the load lock chambers 212, and the pass through stations 206. Transferring the substrates under vacuum facilitates decreasing the chance of contamination, improving the quality of the deposited epitaxial films, and rendering optional the pre-cleaning operation 101 before repetition of the epitaxial growth operation 102 after operations 103 and 105 are conducted. The present disclosure contemplates that one or more of the chambers shown in the system 200 may not be clustered into the cluster tool 201. For example, either or both of the etch chambers 203 and/or the anneal chamber 218 in the system 200 can be separate (not clustered) from the cluster tool 201 having the cleaning chamber 216 and the epitaxy chambers 202. Use of the cleaning chamber 216 is present when the substrate is brought back (from the separate etch chamber and the separate anneal chambers) for repeat of the epitaxy operation 102, unless the cluster tool 201 is capable of receiving a purged FOUP or a portable vacuum station to minimize contamination when the substrate is transferred out and into the cluster tool 201.

In the implementation shown in FIG. 2, the cleaning chamber 216, the epitaxy chambers 202, the etch chambers 203, and the anneal chamber 218 are distinct from each other. In one embodiment, which can be combined with other embodiments, the thermal annealing described for operation 105 is conducted in the epitaxy chambers 202. In such an embodiment, the anneal chamber 218 is not distinct from the epitaxy chambers 202, so that the anneal chamber 218 can be omitted. In one embodiment, which can be combined with other embodiments, each processing chamber of the processing chambers 202 and 203, is a single processing chamber in which each of the operations 101, 102, 103, and 105, the repeating in operation 107, and the repeating in operation 109 are conducted. In such an embodiment, each of the processing chambers 202 (two are shown in FIG. 2) and each of the processing chambers 203 (two are shown in FIG. 2) is a processing chamber in which each of the operations 101, 102, 103, and 105, the repeating in operation 107, and the repeating in operation 109 are conducted. In such an embodiment, the processing chambers 202 are two single processing chambers in each of which the operations 101, 102, 103, and 105, the repeating in operation 107, and the repeating in operation 109 are conducted. In such an embodiment, the processing chambers 203 are two single processing chambers in each of which the operations 101, 102, 103, and 105, the repeating in operation 107, and the repeating in operation 109 are conducted. In one embodiment, which can be combined with other embodiments, each of the cleaning chamber 216 (one is shown in FIG. 2) and the anneal chamber 218 is a single processing chamber in which each of the operations 101, 102, 103, and 105, the repeating in operation 107, and the repeating in operation 109 are conducted.

The system 200 includes a non-transitory computer-readable medium 250 that is configured to control operations of the cluster tool 201. The non-transitory computer-readable medium 250 is coupled to the pods 230, the factory interface 220, the load lock chambers 212, the second transfer chamber 210, the transfer robot 214, the cleaning chamber 216, the epitaxy chambers 202, the first transfer chamber 204, the transfer robot 215, the etch chambers 203, and the anneal chamber 218 to control the operations thereof. The non-transitory computer-readable medium 250 includes instructions that, when executed, cause the cleaning chamber 216, the epitaxy chambers 202, the etch chambers 203, and the anneal chamber 218 to conduct the operations of the method 100. In one embodiment, which can be combined with other embodiments, the non-transitory computer-readable medium 250 is a controller that includes the instructions.

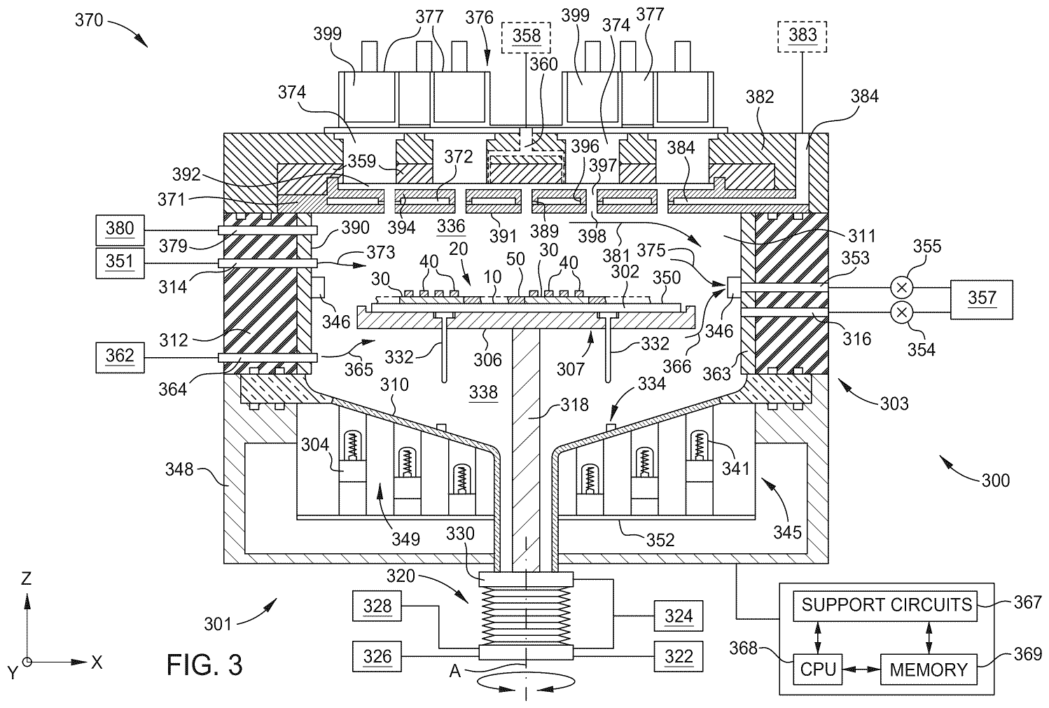

FIG. 3 is a schematic cross-sectional view of a processing chamber 300, according to one implementation. The processing chamber 300 is a single processing chamber that functions as an epitaxy chamber, an etch chamber, and an anneal chamber. The processing chamber 300 can also function as a pre-cleaning chamber. The processing chamber 300 is an epitaxial deposition chamber or a thermal chemical vapor deposition (CVD) chamber equipped with a plasma source of atomic hydrogen. In one embodiment, which can be combined with other embodiments, the processing chamber 300 is a plasma hydrogen chamber.

The processing chamber 300 is part of a system 301 that processes one or more substrates, including the epitaxial deposition of a material on an upper surface of a substrate 302, annealing of the substrate 302, etching of the substrate 302, or combinations thereof. The processing chamber 300 includes a chamber body 303, and an array of radiant heating lamps 304 for heating, among other components, a substrate support 306 disposed within the processing chamber 300, and the substrates 302 positioned on the substrate support 306. The array of radiant heating lamps 304 are disposed in a housing 348 below the substrate support 306. The radiant heating lamps 304 may provide a total lamp power of between about 10 KW and about 60 KW. The radiant heating lamps 304 may heat the substrate 302 to a temperature that is 200 degrees Celsius or higher. The substrate support 306 may be a disk-like substrate support as shown, or may include a ring-like substrate support, which supports the substrate 302 from the edge of the substrate 302, which exposes a backside of the substrate 302 to heat from the radiant heating lamps 304. The substrate support 306 may be formed from silicon carbide or graphite coated with silicon carbide to absorb radiant energy from the lamps 304 and conduct the radiant energy to the substrate 302, thus heating the substrate 302.

The chamber body 303 includes a stainless steel base ring 312 disposed above a floor member 310. The base ring 312 includes one or more sidewalls protected by quartz liners 363. The floor member 310 is conical shaped and transparent. The processing chamber 300 also includes a plasma source lid assembly 370 disposed above the base ring 312. The plasma source lid assembly 370 includes a stainless steel top plate 382, a resonator liner 359, and a quartz gas distribution plate 371. The plasma source lid assembly 370 also includes a resonator assembly 376. The resonator assembly 376 includes a plurality of microwave resonators 374, and a plurality of power sources 399 disposed in resonator housings 377. The resonator liner 359 may be disposed at least partially between the stainless steel top plate 382 and the gas distribution plate 371.

The plasma source lid assembly 370, the base ring 312 of the chamber body 303, and the floor member 310 define an interior volume 311 for the processing chamber 300. The substrate support 306 is located within interior volume 311 above the floor member 310 of the processing chamber 300. The substrate 302 can be transferred into the processing chamber 300 and positioned onto the substrate support 306 through a loading port formed in the base ring 312. Gas injection plenums 314 and 379 and a gas outlet 316 are formed in the base ring 312. The array of radiant heating lamps 304 are disposed outside of the interior volume 311.

The substrate support 306 is rotatable, and includes a shaft or stem 318 that is coupled to a motion assembly 320. The motion assembly 320 includes one or more actuators and/or adjustment devices that provide movement and/or adjustment of the stem 318 and/or the substrate support 306 within the interior volume 311. For example, the motion assembly 320 may include a rotary actuator 322 that rotates the substrate support 306 about a longitudinal axis A of the processing chamber 300. The longitudinal axis A may include a center of an X-Y plane of the processing chamber 300. The motion assembly 320 may include a vertical actuator 324 to lift and lower the substrate support 306 in the Z direction. The motion assembly 320 may include a tilt adjustment device 326 that is used to adjust a planar orientation of the substrate support 306 in the interior volume 311. The motion assembly 320 may also include a lateral adjustment device 328 that is utilized to adjust the positioning of the stem 318 and/or the substrate support 306 side to side within the interior volume 311. In embodiments including a lateral adjustment device 328 and a tilt adjustment device 326, the lateral adjustment device 328 is utilized to adjust positioning of the stem 318 and/or the substrate support 306 in the X and/or Y direction while the tilt adjustment device 326 adjusts an angular orientation (α) of the stem 318 and/or the substrate support 306. In one embodiment, which can be combined with other embodiments, the motion assembly 320 includes a pivot mechanism 330. As the floor member 310 is attached to the processing chamber 300 using the base ring 312, the pivot mechanism 330 is utilized to allow the motion assembly 320 to move the stem 318 and/or the substrate support 306 at least in the angular orientation (α) to reduce stresses on the floor member 310.

The substrate support 306 is shown in an elevated processing position but may be lifted or lowered vertically by the motion assembly 320 as described above. The substrate support 306 may be lowered to a transfer position (below the processing position) to allow lift pins 332 to contact the floor member 310. The lift pins 332 extend through holes 307 in the substrate support 306 as the substrate support 306 is lowered, and the lift pins 332 raise the substrate 302 from the substrate support 306. A transfer robot may then enter the processing chamber 300 to engage and remove the substrate 302 therefrom though the loading port. A new substrate 302 may be loaded onto the lift pins 332 by the transfer robot, and the substrate support 306 may then be actuated up to the processing position to place the substrate 302, with a device side 350 of the substrate 302 facing up. The lift pins 332 include an enlarged head allowing the lift pins 332 to be suspended in openings by the substrate support 306 in the processing position. In one embodiment, which can be combined with other embodiments, stand-offs 334 coupled to the floor member 310 are utilized to provide a flat surface for the lift pins 332 to contact. The stand-offs 334 provide one or more surfaces parallel to the X-Y plane of the processing chamber 300 and may be used to prevent binding of the lift pins 332 that may occur if the end thereof is allowed to contact the curved surface of the transmissive member 310. The stand-offs 334 may be made of an optically transparent material, such as quartz, to allow energy from the lamps 304 to pass therethrough.

The substrate support 306, while located in the processing position, divides the interior volume 311 of the processing chamber 300 into a process gas region 336 that is above the substrate support 306, and a purge gas region 338 below the substrate support 306. The substrate support 306 is rotated during processing by the rotary actuator 322 to minimize the effect of thermal and deposition gas flow spatial anomalies within the processing chamber 300 and thus facilitates uniform processing of the substrate 302. The substrate support 306 may rotate at between about 5 RPM and about 100 RPM, for example, between about 10 RPM and about 50 RPM. The substrate support 306 is supported by the stem 318, which is generally centered on the substrate support 306 and facilitates movement of the substrate support 306 and the substrate 302 in a vertical direction (Z direction) during substrate transfer, and/or processing of the substrate 302.

One or more lamps, such as the array of the radiant heating lamps 304, can be disposed adjacent to and beneath the floor member 310 in a specified manner around the stem 318. The floor member 310 is formed from an optically transparent material such as quartz. The radiant heating lamps 304 may be independently controlled in zones in order to control the temperature of various regions of the substrate 302 as the deposition gas passes thereover, thus facilitating the epitaxial deposition of a material onto the upper surface of the substrate 302.

The radiant heating lamps 304 may include a radiant heat source, depicted here as a lamp bulb 341, and may be configured to heat the substrate 302 to a temperature within a range of about 200 degrees Celsius to about 1,600 degrees Celsius. Each lamp bulb 341 can be coupled to a power distribution board, such as printed circuit board (PCB) 352, through which power is supplied to each lamp bulb 341. A standoff may be used to couple the lamp bulb 341 to the power distribution board, if desired, to change the arrangement of lamps. In one embodiment, which can be combined with other embodiments, the radiant heating lamps 304 are positioned within a lamphead 345 which may be cooled during or after processing by, for example, a cooling fluid introduced into channels 349 located between the radiant heating lamps 304.

During a selective growing operation to selectively grow an epitaxial layer on the substrate 302 (as described for operation 102), one or more deposition gases (which are epitaxial deposition gases) are supplied from process gas sources 351 and/or 380 and introduced into the process gas region 336 through the gas injection plenums 314 and 379 formed in a sidewall of the base ring 312 to couple to the interior volume 311. The deposition gases include one or more of silicon, phosphorous and/or boron or the other dopants described herein, germanium, hydrogen chloride, chlorine, and/or one or more carrier gases. The one or more carrier gases includes one or more of H₂, N₂, Ar, and/or He. The gas injection plenums 314 and 379 are coupled to a side 390 of the interior volume 311 to deliver the one or more deposition gases through the side 390 of the interior volume 311.

In the implementation shown in FIG. 3, the gas injection plenums 314 and 379 are configured to direct the deposition gases in a generally radially inward direction. As such, the gas injection plenum 314 may be part of a cross-flow gas injector. The cross-flow gas injector is positioned to direct the deposition gases across a surface of the substrate support 306 and/or the substrate 302. During an epitaxial layer growth operation, the substrate support 306 is located in the processing position, which is adjacent to and at about the same elevation as the gas injection plenums 314 and 379, thus allowing the deposition gases to flow generally along flow path 373 across the upper surface of the substrate support 306 and/or substrate 302. The deposition gases exit the process gas region 336 (along flow path 375) through the gas outlet 316 located on the opposite side of the processing chamber 300 as the gas injection plenums 314 and 379. Removal of the deposition gases through the gas outlet 316 may be facilitated by a vacuum pump 357 coupled thereto.

A pumping ring 346 may be optionally disposed around the substrate support 306 and adjacent to a liner 363 disposed on an inner side of the base ring 312. The pumping ring 346 is an alternate path for pumping gases out of the interior volume 311 via an outlet path 353 and a valve 355. In one embodiment, which can be combined with other embodiments, in conjunction with the use of the pumping ring 346, deposition gases may be alternatively introduced into the process gas region 336 via an internal plenum 372 of the gas distribution plate 371 from a gas source 383 and a channel 384. Holes 389 in sidewalls 396 of the gas distribution plate 371 allow deposition gases to exit the internal plenum 372 and enter the process gas region 336 via openings 398. The pumping ring 346 may also serve as a pre-heat zone for the deposition gases. The pumping ring 346 may be made from CVD SiC, sintered graphite coated with SiC, grown SiC, opaque quartz, coated quartz, or any similar, suitable material that is resistant to chemical breakdown by process and purge gases. Gases enter an inner circular plenum of the pumping ring 346 via holes all around the top and bottom surfaces of the pumping ring 346.

Purge gas supplied from a purge gas source 362 is introduced to the purge gas region 338 through a purge gas inlet 364 formed in the sidewall of the base ring 312. The purge gas inlet 364 is disposed at an elevation below the gas injection plenum 314. If the pumping ring 346 is used, the pumping ring 346 may be disposed between the gas injection plenum 314 and the purge gas inlet 364. In either case, the purge gas inlet 364 is configured to direct the purge gas in a generally radially inward direction. The purge gas inlet 364 may be configured to direct the purge gas in an upward direction. During an epitaxial layer growth operation, the substrate support 306 is located at a position such that the purge gas flows generally along flow path 365 across a back side of the substrate support 306. The purge gas exits the purge gas region 338 (along flow path 366) and is exhausted out of the processing chamber 300 through the gas outlet 316 located on the opposite side of the processing chamber 300 as the purge gas inlet 364.

During an etching operation including exposing the substrate 302 to atomic hydrogen radicals (as described for operation 103), the process gas sources 351 and 380 are inactive such that the deposition gas is not introduced into the processing chamber 300. During the etching operation, helium (He), and/or argon (Ar) gases are introduced into the plasma source lid assembly 370 from a gas source 358 and a gas channel 360, and the microwave resonators 374 are active (e.g., powered). In one embodiment, which can be combined with other embodiments, the gas channel 360 (which is coupled to the gas source 358) extends vertically through the top plate 382 and a resonator liner 359 of the lid assembly 370. Gases from the gas source 358 flow along outer sides of the microwave resonators 374 (as illustrated for the gas channel 360 shown in ghost in FIG. 3). In such an embodiment, the gas source 358 is in fluid communication with the regions 392 and 397 of the lid assembly 370. Region 392 is bounded by the top surface 394 of gas distribution plate 371 and the bottom of the resonator liner 359. Region 397 is the top opening of the gas distribution plate 371.

The plasma includes atomic hydrogen radicals by including hydrogen H₂ from the gas source 358. The plasma species produced when the microwave resonators 374 are active, including the atomic hydrogen radicals, exit the region 397 of the plasma source lid assembly 370 and are delivered to the interior volume 311 through an opening 398 (a plurality of openings 398 are shown in FIG. 3) at a bottom surface 391 of the gas distribution plate 371. The bottom surface 391 of the gas distribution plate 371 serves as the ceiling of the interior volume 311. In one embodiment, which can be combined with other embodiments, to reduce or minimize residence time of hydrogen radicals in the regions 392 and 397, hydrogen is alternatively separately introduced into an internal plenum 372 of the gas distribution plate 371 from a gas source 383 and a channel 384. In this case, atomic hydrogen produced close to the opening 398 upon exiting plenum 372 via holes 389 in the sidewalls 396 has little time to recombine inside the gas distribution plate 371. One or more non-crystalline surfaces of the substrate 302 are exposed to the atomic hydrogen radicals. The atomic hydrogen radicals react with a plurality of nodules grown on the one or more non-crystalline surfaces of the substrate 302 to remove the plurality of nodules from the one or more non-crystalline surfaces of the substrate 302 while maintaining the epitaxial layer formed on the one or more crystalline surfaces.

During and/or following the etching, etched byproducts can be pumped out of the processing chamber 300 using the pumping ring 346. In one embodiment, which can be combined with other embodiments, a first flow valve 354 is closed and a second flow valve 355 is open during etching to pump out the etched byproducts.

During a thermal anneal operation (as described for operation 105), one or more anneal gases are introduced into the processing chamber 300 from the process gas source 351 through the gas injection plenum 314. The anneal gases follow the flow paths 373, 375 described for the deposition gases, and are exposed to the substrate 302. During the thermal anneal operation, the purge gas is introduced through the purge gas inlet 364, and optionally the gases from the plasma source lid assembly 370 are introduced while the microwave resonators 374 are inactive (e.g., unpowered). During the thermal anneal operation, the radiant heating lamps 304 heat the substrate 302 to the anneal temperature that is 600 degrees Celsius or higher while the substrate 302 is exposed to the one or more anneal gases.

The system 301 also includes the non-transitory computer-readable medium 250 (shown in FIG. 2) coupled to the processing chamber 300 to control operations of the processing chamber 300. The non-transitory computer-readable medium 250 includes support circuits 367, a central processing unit (CPU) 368 and a memory 369 that includes the instructions. The instructions are executed by the CPU 368.

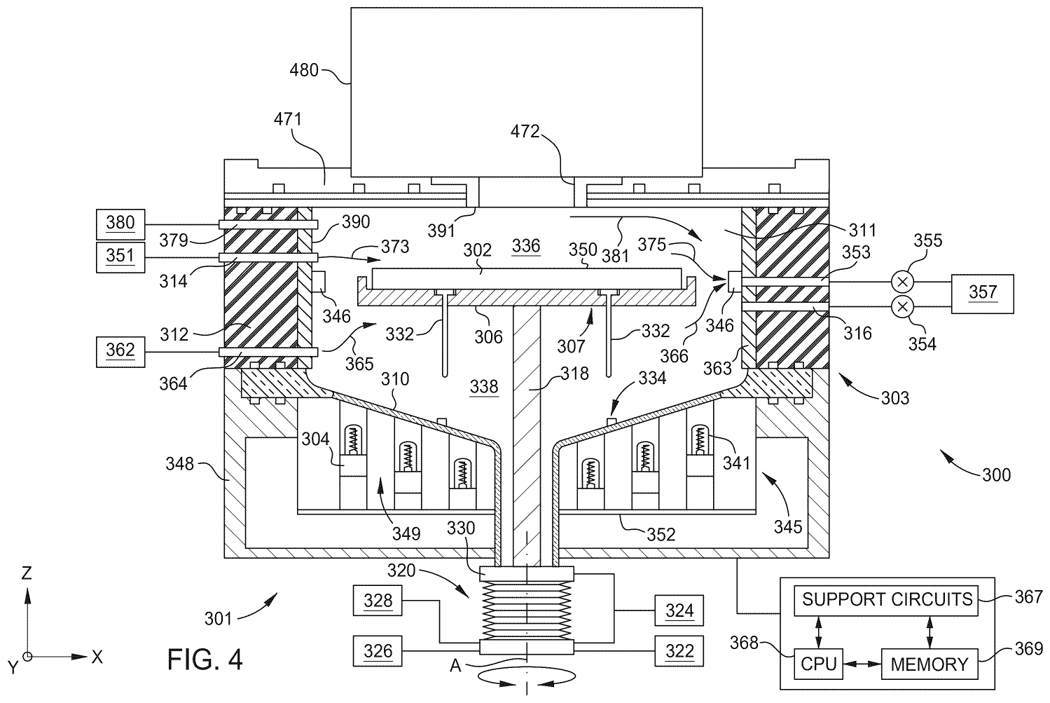

FIG. 4 is a schematic cross-sectional view of a processing chamber 400, according to one implementation. The processing chamber 400 is a part of a system 401 that is similar to the system 301. The processing chamber 400 is similar to the processing chamber 300 shown in FIG. 3, and includes one or more of the aspects, features, components, and/or properties thereof. The processing chamber 400 is a thermal chemical vapor deposition (CVD) chamber equipped with a remote plasma source of atomic hydrogen.

The remote plasma source 480 is coupled to the ceiling 391 of the interior volume 311 through a central opening 472 of a lid assembly 471. The remote plasma source 480 is an inductively coupled plasma (“ICP”) source or a microwave plasma source. The remote plasma source 480 receives Hydrogen (H2), Helium, and/or Argon from a gas source, and generates the hydrogen plasma in the remote plasma source 480. The hydrogen plasma source having the atomic hydrogen radicals is introduced into the interior volume 311 through the ceiling 391 to expose the substrate 302 to the atomic hydrogen radicals. The one or more deposition gases can be introduced into the interior volume 311 of the processing chamber 400 according to any way described for FIG. 3.

In one embodiment, which can be combined with other embodiments, the remote plasma source 480 includes a diameter (taken along the X-Y plane) that is equal to our larger than a diameter of the substrates 302. The X-Y plane is parallel to the device side 350 of the substrate 302.

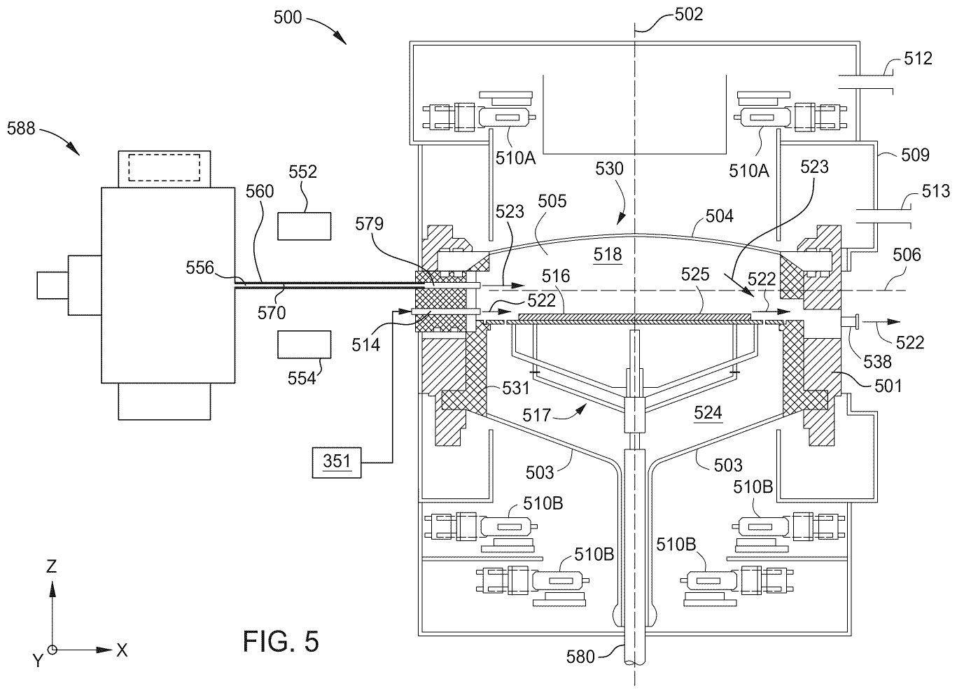

FIG. 5 is a schematic cross-sectional view of a processing chamber 500, according to one implementation. The processing chamber 500 includes a housing structure 501 made of a process resistant material, such as aluminum or stainless steel, for example 316 L stainless steel. The housing structure 501 encloses various functioning elements of the chamber 500, such as a quartz chamber 530, which includes an upper quartz chamber 505, and a lower quartz chamber 524, in which an interior volume 518 is contained. The processing chamber 500 includes the process gas source 351 to introduce the one or more deposition gases and/or the one or more anneal gases into the interior volume 518. The process gas source 351 is coupled to a gas injection plenum 514 formed in a sidewall of one or more sidewalls of the processing chamber 500.

The processing chamber 500 includes a remote plasma source 588 that is coupled to a plasma opening 579 by a conduit 560. The plasma opening 579 is formed in a sidewall of the one or more sidewalls of the processing chamber 500. The conduit 560 defines an inlet 556, which may have a first inner diameter and a second inner diameter that is larger than the first inner diameter. The first inner diameter may be disposed adjacent to the remote plasma source 588 and the second inner diameter may be disposed adjacent to the plasma opening 579. In one example, first inner diameter may be about 12 mm to about 30 mm, for example about 20 mm, and the second inner diameter may be about 35 mm to about 60 mm, for example about 40 mm. The conduit 560 is configured to filter ions generated in the remote plasma source 588 before entering the quartz chamber 530, while allowing electrically neutral atomic hydrogen radicals to enter the quartz chamber 530. The relative concentration of ions in the interior volume 518 is reduced. In one implementation, the gases flowing through the inlet 556 are filtered by a magnetic field generated by one or more magnets disposed adjacent to the conduit 560. The magnets generate a magnetic field across the conduit 560 to filter charged particles entrained with the reactive radicals flowing from the remote plasma source 588.

In the implementation shown, a first magnet 552 and a second magnet 554 are disposed adjacent to the conduit 560. The first magnet 552 and second magnet 554 may be permanent magnets or electromagnets. The magnets 552, 554 may be disposed opposite from each other across the first inner diameter of the conduit 560. For example, the magnets 552, 554 may be adhered or secured on opposite sides of an outer periphery of the conduit 560. The magnets 552, 554 may alternately be secured to a sidewall of the processing chamber 500 or other components of the processing chamber 500. The relative distance between the opposed magnet and the inlet 556 formed within the conduit 560 affects the strength of the magnetic field passing through the inlet 556, and thereby affects the filtering efficiency. The magnetic field may also be adjusted by using different magnets, e.g., replacing magnets 552, 554 with different strength. The passing charged particles are drawn in contact with an inner surface 570 of the conduit 560 and become electrically neutral, non-ionic species. As such, the filtered, electrically neutral radicals are delivered to the surface of the substrate to react with and etch nodules thereon.

Gases and processing byproducts are removed from the interior volume 518 by an outlet 538 in communication with a vacuum source. A substrate support 517 is adapted to receive a substrate 525 that is transferred to the interior volume 518. The substrate support 517 is disposed along a longitudinal axis 502 of the chamber 500. The one or more deposition gases, the atomic hydrogen radicals, and the anneal gases are respectively applied to a surface 516 of the substrate 525, and byproducts may be subsequently removed from the surface 516. Heating of the substrate 525 and/or the interior volume 518 may be provided by radiation sources, such as upper lamp modules 510A and lower lamp modules 510B.

The upper lamp modules 510A and lower lamp modules 510B are infrared (IR) lamps in a lamp housing 509. Non-thermal energy or radiation from lamp modules 510A and 510B travels through upper quartz window 504 (e.g., an upper dome) of upper quartz chamber 505, and through a lower quartz window 503 (e.g., a lower dome) of lower quartz chamber 524. Cooling gases for upper quartz chamber 505, if needed, enter through an inlet 512 and exit through the outlet port 513. The deposition gases, the anneal gases, and the atomic hydrogen radicals enter respectively through the gas injection plenum 514 and the plasma opening 579, and exit through outlet 538. While the upper quartz window 504 is shown as being curved or convex, the upper quartz window 504 may be planar with sufficient thickness to withstand the differential pressure across both sides of the upper quartz window. The substrate support 517 is supported on a stem 580 that extends through a central opening of the lower quartz window 503.

During epitaxial deposition, the low wavelength radiation in the interior volume 518, which is used to energize reactive species and assist in adsorption of reactants and desorption of process byproducts from the surface 516 of substrate 525, typically ranges from about 0.8 μm to about 1.2 μm, for example, between about 0.95 μm to about 1.05 μm, with combinations of various wavelengths being provided, depending, for example, on the composition of the film which is being epitaxially grown.

The deposition gases and the anneal gases, shown by flow path 522, enter through the gas injection plenum 514 and exit through outlet 538. The atomic hydrogen radicals, shown by numeral 523, enter through the plasma opening 579 and exit through the outlet 538, which is a port. Combinations of component gases, which are used to form the silicon and/or germanium-containing film that is being epitaxially grown, or to etch the nodules, are typically mixed prior to entry into the processing volume. The overall pressure in the interior volume 518 may be adjusted by a valve on the outlet 538. At least a portion of the interior surface of the interior volume 518 is covered by a liner 531. In one embodiment, which can be combined with other embodiments, the liner 531 includes a quartz material that is opaque. In this manner, the chamber wall is insulated from the heat in the interior volume 518.

The temperature of surfaces in the interior volume 518 may be controlled within a temperature range of about 200 degrees Celsius to about 600 degrees Celsius, or greater, by the combination of water cooling to the housing structure 501, flow of a cooling gas for the upper and lower quartz windows, and the radiation from upper and lower lamp modules 510A and 510B positioned respectively above upper quartz window 504 and lower quartz window 503. The pressure in the interior volume 518 may be between about 0.1 Torr to about 600 Torr, such as between about 5 Torr to about 30 Torr.

The temperature on the substrate 525 surface 516 may be controlled by power adjustment to the lower lamp modules 510B in lower quartz chamber 524, or by power adjustment to both the upper lamp modules 510A overlying the upper quartz window 504, and the lower lamp modules 510B in lower quartz chamber 524. The power density in the interior volume 518 may be between about 40 W/cm2 to about 400 W/cm2, such as about 80 W/cm2 to about 120 W/cm2.

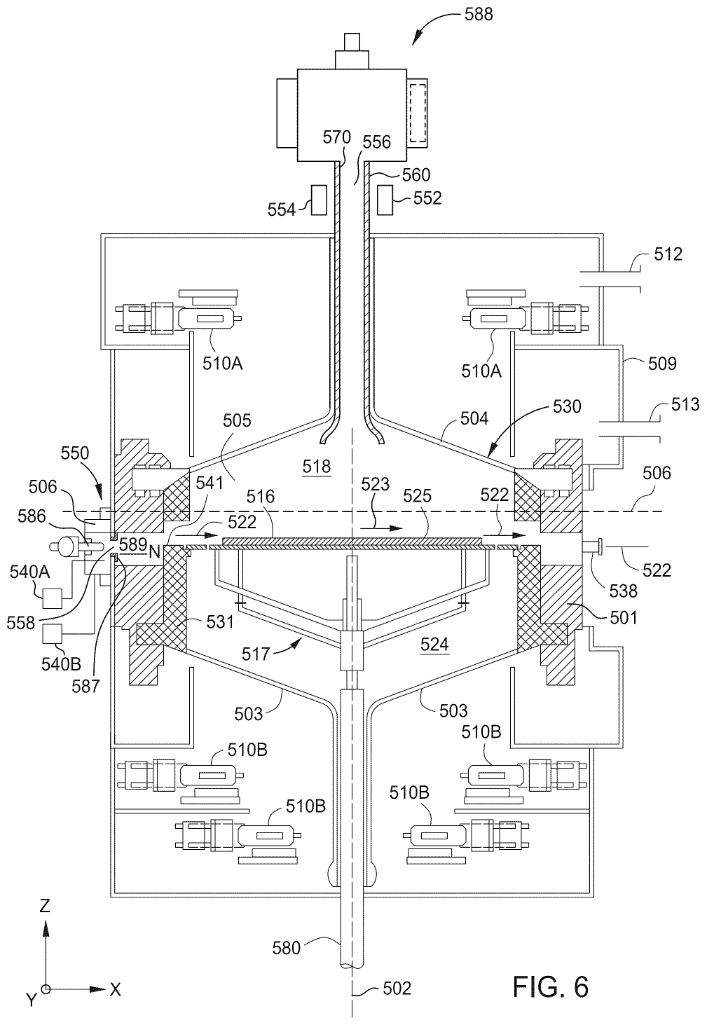

FIG. 6 is a schematic cross-sectional view of a processing chamber 600, according to one implementation. The processing chamber 600 is similar to the processing chamber 500 shown in FIG. 5, and includes one or more of the aspects, features, components, and/or properties thereof.

The deposition gases and the anneal gases are provided to the quartz chamber 530 by a gas distribution assembly 550, and processing byproducts are removed from the interior volume 518 by the outlet 538 in communication with a vacuum source. The deposition gases, carrier gases and purge gases are applied to the surface 516 of the substrate 525, and byproducts may be subsequently removed from the surface 516. Gas flows from the gas distribution assembly 550 and exits through port 538 as shown generally at 522.

In one aspect, the gas distribution assembly 550 is disposed normal to, or in a radial direction 506 relative to, the longitudinal axis 502 of the chamber 600 or substrate 525. In this orientation, the gas distribution assembly 550 is adapted to flow process gases in a radial direction 506 across, or parallel to, the surface 516 of the substrate 525. In one processing application, the process gases are preheated at the point of introduction to the chamber 600 to initiate preheating of the gases prior to introduction to the interior volume 518, and/or to break specific bonds in the gases. In this manner, surface reaction kinetics may be modified independently from the thermal temperature of the substrate 525.

The processing chamber 600 includes the remote plasma source 588 coupled to the interior volume 518 through a central opening of the upper quartz window 504. The conduit 560 of the remote plasma source 588 is received through the central opening of the upper quartz window 504 and opens up into the interior volume 518.

In operation, precursors to form epitaxial films are provided to the gas distribution assembly 550 from the one or more gas sources 540A and 540B. IR lamps 586 (only one is shown in FIG. 6) may be utilized to heat the precursors within the gas distribution assembly 550 as well as along the flow path 522. The gas sources 540A, 540B may be coupled the gas distribution assembly 550 in a manner configured to facilitate introduction zones within the gas distribution assembly 550, such as a radial outer zone and a radial inner zone between the outer zones when viewed in from a top plan view. The gas sources 540A, 540B may include valves to control the rate of introduction into the zones.

The gas sources 540A, 540B may include silicon-containing precursors such as one or more silanes, such as silane (SiH₄), disilane (Si₂H₆), dichlorosilane (SiH₂Cl₂), hexachlorodisilane (Si₂Cl₆), dibromosilane (SiH₂Br₂), and/or higher order silanes, derivatives thereof, and/or combinations thereof. The gas sources 540A, 540B may include one or more germanium-containing precursors, such as germane (GeH₄), digermane (Ge₂H₆), germanium tetrachloride (GeCl₄), dichlorogermane (GeH₂Cl₂), and/or derivatives thereof, and/or combinations thereof. The silicon and/or germanium containing precursors may be used in combination with hydrogen chloride (HCl), chlorine gas (Cl₂), and/or hydrogen bromide (HBr), and/or combinations thereof. The gas sources 540A, 540B may include one or more of the silicon and germanium containing precursors in one or both of the gas sources 540A, 540B. The gas sources 540A, 540B may include one or more carrier gases such as H₂, N₂, Ar, and/or He. The gas sources 540A, 540B may include one or more dopant gases. In one embodiment, which can be combined with other embodiments, the one or more dopant gases include one or more of diborane (B₂H₆), boron trichloride (BCl₃), phosphine, phosphorous trichloride (PCl₃), tertiarybutylphosphine (TBP), silylphosphines, arsine (AsH₃), tertiarybutylarsine (TBA), triethylantimony (TESb), tin chloride (SnCl₄), and trimethylgallium (TMGa).

The precursor materials enter the interior volume 518 through openings or a plurality of holes 558 (only one is shown in FIG. 6) in the perforated plate 587 in this excited state, which in one embodiment is a quartz material, having the holes 558 formed therethrough. The perforated plate 587 is transparent to IR energy, and may be made of a clear quartz material. In other embodiments, the perforated plate 587 may be any material that is transparent to IR energy and is resistant to process chemistry and other process chemistries. The energized precursor materials flow toward the interior volume 518 through the plurality of holes 558 in the perforated plate 587, and through a plurality of channels 589 (only one is shown in FIG. 6). A portion of the photons and non-thermal energy from the IR lamps 586 also passes through the holes 558, the perforated plate 587, and channels 589 facilitated by a reflective material and/or surface disposed on the interior surfaces of the gas distribution assembly 550, thereby illuminating the flow path 522 of the precursor materials. In this manner, the vibrational energy of the precursor materials may be maintained from the point of introduction to the interior volume 518 along the flow path 522.

Benefits of the present disclosure include removing residual or non-selective growth (e.g., nodules) in undesired locations at a reduced or eliminated probability of damage to or interference with epitaxial layers in desired locations.

It is contemplated that one or more aspects disclosed herein may be combined. As an example, one or more aspects, features, components, and/or properties of the method 100, the system 200, the system 301, the system 401, the processing chamber 500, and/or the processing chamber 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A system for processing substrates, comprising:
a processing chamber comprising:
an interior volume disposed between a plurality of chamber walls, wherein
the plurality of chamber walls comprise an upper wall, a lower wall, a first side wall and a second side wall, and
the interior volume is disposed between the first side wall and the second side wall;
a substrate support positioned within the interior volume and between the upper wall and the lower wall; and
a first array of radiant heat sources positioned to deliver electromagnetic radiation to the substrate support through the lower wall;
a plasma source comprising an inlet and an outlet, wherein the outlet is coupled to a gas inlet opening formed in the first side wall or the upper wall of the processing chamber;
an exhaust system comprising a pump coupled to a gas outlet opening formed in the second side wall; and
a gas source assembly coupled to the inlet of the plasma source, wherein
the gas source assembly comprises process gas delivery components configured to control a flow of a first process gas from an external gas source to the inlet of the plasma source; and
the plasma source is operable to generate a plasma comprising the first process gas and supply radicals generated in the plasma to the interior volume through the outlet of the plasma source.

2. The system of claim 1, wherein the processing chamber further comprises a quartz liner disposed between the first side wall and the interior volume, and between the interior volume and the second side wall.

3. The system of claim 2, wherein the outlet of the plasma source is in fluid communication with the interior volume through the gas inlet opening formed in the first side wall and an opening formed in the quartz liner.

4. The system of claim 1, wherein the processing chamber further comprises a second array of radiant heat sources positioned to deliver electromagnetic radiation to the substrate support through the upper wall.

5. The system of claim 1, wherein the first process gas comprises hydrogen.

6. The system of claim 1, wherein the gas source assembly further comprises process gas delivery components configured to control a flow of a second process gas from the external gas source to the interior volume through an opening formed in the first side wall.

7. The system of claim 6, further comprising a controller comprising instructions that, when executed, cause:
a flow of the first process gas from the outlet of the plasma source, through a first opening formed in the first side wall, over a surface of the substrate support, and through an opening formed in the second side wall; and
simultaneous supply the second process gas to the interior volume through the first opening or a second opening formed in the first side wall,
wherein the first process gas flowing from the outlet of the plasma source comprises hydrogen radicals, and the second process gas comprises a silicon-containing precursor.

8. The system of claim 1, wherein the processing chamber further comprises a gas distribution plate disposed between the substrate support and the outlet of the plasma source.

9. The system of claim 8, wherein the plasma source comprises a plurality of microwave resonators and a resonator liner disposed between the inlet and the outlet of the plasma source.

10. The system of claim 8, wherein the gas distribution plate comprises a plurality of first openings formed in a surface of the gas distribution plate, and a plurality of second openings extending to an internal plenum of the gas distribution plate.

11. The system of claim 1, wherein
the plasma source comprises an inductive coupled source, and
the gas source assembly further comprises process gas delivery components configured to provide an argon containing gas to the inlet of the plasma source.

12. The system of claim 1, wherein the outlet of the plasma source is coupled to an opening formed in the upper wall of the processing chamber.

13. A system for processing substrates, comprising:
a processing chamber comprising:
an interior volume disposed between a plurality of chamber walls, wherein
the plurality of chamber walls comprise an upper wall, a lower wall, a first side wall and a second side wall, and
the interior volume is disposed between the first side wall and the second side wall;
a substrate support positioned within the interior volume and between the upper wall and the lower wall;
a gas distribution plate positioned between the upper wall and the substrate support, wherein the gas distribution plate comprises a plurality of distribution plate openings; and
a first array of radiant heat sources positioned to deliver electromagnetic radiation to the substrate support through the lower wall;
a plasma source comprising an inlet and the plurality of distribution plate openings of the gas distribution plate form an outlet of the plasma source;
an exhaust system comprising a pump coupled to a gas outlet opening formed in the second side wall;
a first gas source assembly coupled to the inlet of the plasma source, wherein
the gas source assembly comprises process gas delivery components configured to control a flow of a first process gas to the inlet of the plasma source; and
the plasma source is operable to generate a plasma comprising the first process gas and supply radicals generated in the plasma to the interior volume through the outlet of the plasma source; and
a second gas source assembly coupled to a gas inlet opening formed in the first side wall, wherein the second gas source assembly comprises process gas delivery components configured to control a flow of a second process gas to the gas inlet opening formed in the first side wall.

14. The system of claim 13, wherein the processing chamber further comprises a quartz liner disposed between the first side wall and the interior volume, and between the interior volume and the second side wall.

15. The system of claim 13, wherein the processing chamber further comprises a second array of radiant heat sources positioned to deliver electromagnetic radiation to the substrate support through the upper wall.

16. The system of claim 13, wherein the first process gas comprises hydrogen.

17. The system of claim 16, wherein the second process gas comprises a silicon-containing gas.

18. The system of claim 17, further comprising a controller comprising instructions that, when executed, cause:
a flow of the first process gas from the outlet of the plasma source and to a surface of the substrate support; and
simultaneously supplying the second process gas to the interior volume through the gas inlet opening formed in the first side wall.

19. The system of claim 13, wherein the upper wall and the lower wall comprise quartz.

20. The system of claim 13, wherein the plasma source comprises an inductive coupled source.
